(19) United States
(12) Patent Application Publication
(10) Pub. No.: US 2026/0130281 A1
(43) Pub. Date: May 7, 2026

(54) PACKAGE STRUCTURE AND METHOD OF FABRICATING THE SAME

(71) Applicant: Taiwan Semiconductor Manufacturing Company, Ltd., Hsinchu (TW)

(72) Inventors: Cheng-Xuan Wu, Hsinchu (TW); Chia-Peng Sun, Hsinchu (TW); Kai-Cheng Chen, Taoyuan City (TW); Wen-Yi Lin, New Taipei City (TW); Zhihua Zou, Hsinchu (TW)

(73) Assignee: Taiwan Semiconductor Manufacturing Company, Ltd., Hsinchu (TW)

(21) Appl. No.: 18/938,169

(22) Filed: Nov. 5, 2024

(51) Int. Cl. H01L 25/16; H01L 21/48; H01L 23/498; H01L 23/538

(52) U.S. Cl. CPC H10W 90/00; H10W 70/093; H10W 70/611; H10W 70/65; H10W 70/685; H10W 90/701

(57) ABSTRACT

A package structure includes a circuit substrate and a semiconductor package disposed on and electrically connected to the circuit substrate. The semiconductor package includes and interconnection structure, first passive devices, second passive devices and bump structures. The first passive devices are electrically connected to the interconnection structure, and arranged as a first pattern in between the interconnection structure and the circuit substrate. The second passive devices are electrically connected to the interconnection structure, and arranged as a second pattern in between the interconnection structure and the circuit substrate, wherein the second pattern is different from the first pattern. The bump structures are electrically connecting the interconnection structure to the circuit substrate and laterally surrounding the first passive devices and the second passive devices.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 12 are schematic sectional and top views of various stages in a method of fabricating a package structure according to some exemplary embodiments of the present disclosure.

FIG. 13 is a schematic top view from a second surface of an interconnection structure in a package structure according to some exemplary embodiments of the present disclosure.

FIG. 14 is a schematic top view from a second surface of an interconnection structure in a package structure according to some other exemplary embodiments of the present disclosure.

FIG. 15 is a schematic top view from a second surface of an interconnection structure in a package structure according to some other exemplary embodiments of the present disclosure.

FIG. 16 is a schematic sectional view of a package structure according to some other exemplary embodiments of the present disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

During the fabrication of package structures, an underfill structure is generally formed in between a circuit substrate and an interconnection structure of a semiconductor package to protect and surround bump structures and integrated passive devices (IPDs). Due to the orthogonal grid-like pattern arrangement (or parallel arrangement) of the IPDs on the interconnection structure, there is a high risk of forming voids during the filling of an underfill material to surround the IPDs and the bump structures. For example, when the underfill material if filled into a bump-free zone of the IPDs, the different capillary pressure between the bump-free zone of the IPDs and the surrounding bump structures will cause the underfill flow rate to be highly different, resulting in the formation of voids or air traps. In accordance with some embodiments of the present disclosure, a package structure is formed so that a risk of underfill voids or formation of air traps can be reduced, and the yield and reliability of the package are enhanced.

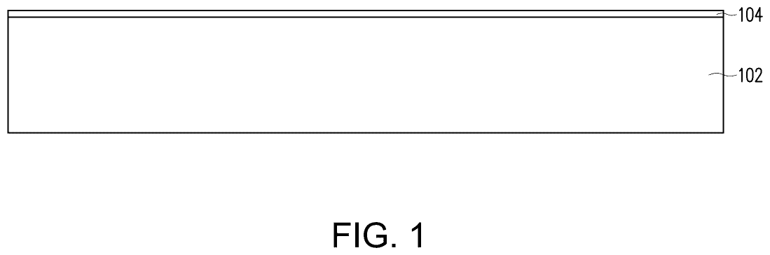

FIG. 1 to FIG. 12 are schematic sectional and top views of various stages in a method of fabricating a package structure according to some exemplary embodiments of the present disclosure. Referring to FIG. 1, a carrier 102 is provided. In some embodiments, the carrier 102 may be a glass carrier or any suitable carrier for carrying a semiconductor wafer or a reconstituted wafer for the manufacturing method of the package structure. In some embodiments, the carrier 102 is coated with a debond layer 104. The material of the debond layer 104 may be any material suitable for bonding and de-bonding the carrier 102 from the above layer(s) or any wafer(s) disposed thereon.

In some embodiments, the debond layer 104 may include a dielectric material layer made of a dielectric material including any suitable polymer-based dielectric material (such as benzocyclobutene (“BCB”), polybenzoxazole (“PBO”)). In an alternative embodiment, the debond layer 104 may include a dielectric material layer made of an epoxy-based thermal-release material, which loses its adhesive property when heated, such as a light-to-heat-conversion (LTHC) release coating film. In a further alternative embodiment, the debond layer 104 may include a dielectric material layer made of an ultra-violet (UV) glue, which loses its adhesive property when exposed to UV lights. In certain embodiments, the debond layer 104 may be dispensed as a liquid and cured, or may be a laminate film laminated onto the carrier 102, or may be the like. The top surface of the debond layer 104, which is opposite to a bottom surface contacting the carrier 102, may be levelled and may have a high degree of coplanarity. In certain embodiments, the debond layer 104 is, for example, a LTHC layer with good chemical resistance, and such layer enables room temperature de-bonding from the carrier 102 by applying laser irradiation, however the disclosure is not limited thereto.

In an alternative embodiment, a buffer layer (not shown) may be coated on the debond layer 104, where the debond layer 104 is sandwiched between the buffer layer and the carrier 102, and the top surface of the buffer layer may further provide a high degree of coplanarity. In some embodiments, the buffer layer may be a dielectric material layer. In some embodiments, the buffer layer may be a polymer layer which made of polyimide, PBO, BCB, or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

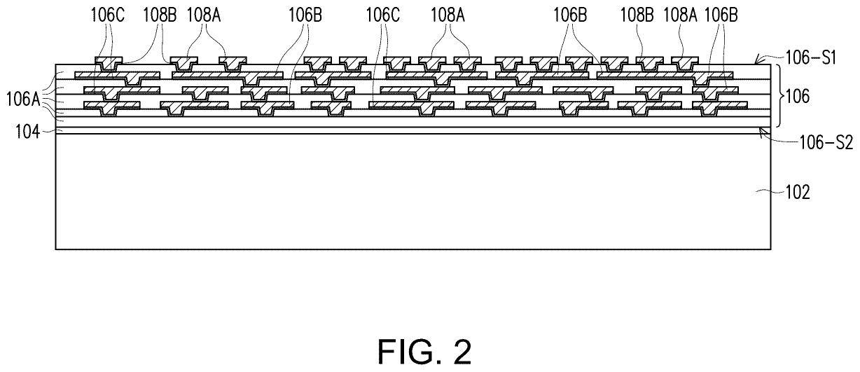

Referring to FIG. 2, in a subsequent step, an interconnection structure 106 (or redistribution layer) is formed on the debond layer 104. In some embodiments, forming the interconnection structure 106 includes forming a plurality of dielectric layers 106A, a plurality of conductive elements 106B, and a plurality of seed layers 106C alternately stacked up along a build-up direction. The number of layers of the dielectric layers 106A, the number of layers of the conductive elements 106B, and the number of layers of the seed layers 106C are not particularly limited, and may be adjusted based on product requirement. In the exemplary embodiment, the seed layers 106C are conformally formed on the dielectric layers 106A, and formed in openings of the dielectric layers 106A. Furthermore, the conductive elements 106B are formed over the seed layers 106C, and may include conductive vias and conductive lines for providing interconnection.

In some embodiments, the material of the dielectric layers 106A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layers 106A are formed by suitable fabrication techniques such as spin-on coating, chemical vapor deposition (CVD), plasma-enhanced chemical vapor deposition (PECVD) or the like. The disclosure is not limited thereto.

In some embodiments, a material of the conductive elements 106B may include conductive materials formed by electroplating or deposition, such as aluminum, titanium, copper, nickel, tungsten, and/or alloys thereof, which may be patterned using a photolithography and etching process. In some embodiments, the conductive elements 106B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. In some embodiments, the material of the seed layers 106C include titanium, or the like. The seed layers 106C may be formed using, for example, PVD, or the like.

In some embodiments, in a subsequent step, a plurality of seed layers 108B and a plurality of bonding pads 108A are formed over a topmost layer of the plurality of conductive elements 106B. For example, the seed layers 108B are electrically connected to a top surface of the conductive elements 106B, while the bonding pads 108A are disposed on and electrically connected to the conductive elements 106B through the seed layers 108B. In some embodiments, a material of the seed layers 108B is similar to a material of the seed layers 106C, and a material of the bonding pads 108A is similar to a material of the conductive elements 106B, thus their detailed description will be omitted herein.

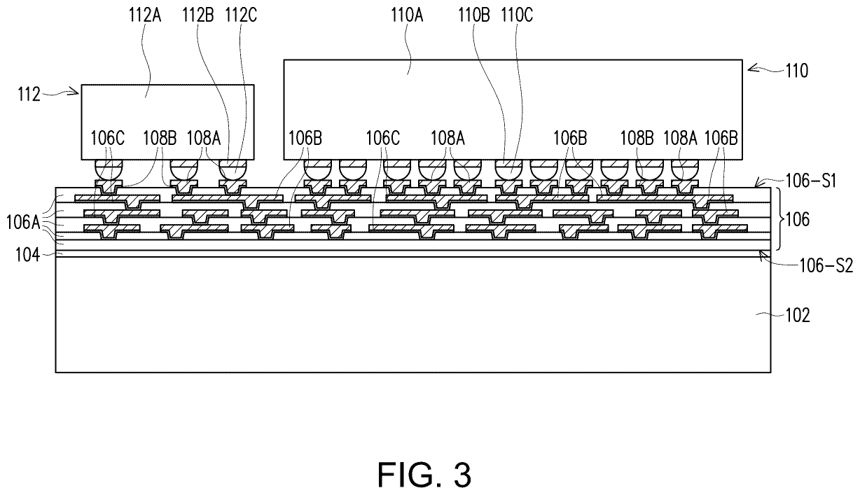

Referring to FIG. 3, after forming the bonding pads 108A of the interconnection structure 106, a first semiconductor die 110 and a second semiconductor die 112 are provided over the interconnection structure 106 for bonding. Although only two semiconductor dies are illustrated herein, it is noted that there may in fact be more than two dies provided for bonding to the interconnection structure 106. For example, in one exemplary embodiment, there are one first semiconductor die 110, and three second semiconductor dies 112 that are bonded to and electrically connected to the interconnection structure 106. In the exemplary embodiment, the first semiconductor die 110 and the second semiconductor dies 112 are individual dies singulated from a wafer. The backsides of the second semiconductor dies 112 may be grinded or partially removed so that is has a reduced thickness relative to the thickness of the first semiconductor die 110.

In some embodiments, the first semiconductor die 110 and the second semiconductor die 112 have different circuitry or are different types of dies. In some embodiments, from a top view of the first and second semiconductor dies 110, 112 (not shown), the first semiconductor die 110 have a surface area larger than that of the second semiconductor dies 112, but the disclosure is not limited thereto. In some embodiments, the first semiconductor die 110 may be a logic die, including a central processing unit (CPU) die, graphics processing unit (GPU) die, system-on-a-chip (SoC) die, a microcontroller or the like. In some embodiments, the second semiconductor die 112 may be a memory die, including dynamic random access memory (DRAM) die, static random access memory (SRAM) die or a high bandwidth memory (HBM) die.

As further illustrated in FIG. 3, the first semiconductor die 110 include a body 110A and connecting pads 110B formed on an active surface of the body 110A. In certain embodiments, the connecting pads 110B may further include conductive bumps 110C for bonding the first semiconductor die 110 to the bonding pads 108A on the interconnection structure 106. Similarly, in some embodiments, the second semiconductor die 112 include a body 112A and connecting pads 112B formed on an active surface of the body 112A. In certain embodiments, the connecting pads 112B may further include conductive bumps 112C for bonding the second semiconductor dies 112 to the bonding pads 108A on the interconnection structure 106. In some embodiments, the conductive bumps 110C, 112C are micro-bumps, such as micro-bumps having copper metal pillars. In another embodiment, the conductive bumps 110C, 112C are solder bumps, lead-free solder bumps, or micro bumps, such as controlled collapse chip connection (C4) bumps or micro bumps containing copper pillars.

In some embodiments, the first semiconductor die 110 and the second semiconductor die 112 are attached to the bonding pads 108A on the interconnection structure 106, for example, through flip-chip bonding by way of the conductive bumps 110C, 112C. Through a reflow process, the conductive bumps 110C, 112C are arranged between the connecting pads 110B, 112B and the bonding pads 108A of the interconnection structure 106, and are electrically and physically connecting the first and second semiconductor dies 110, 112 to the interconnection structure 106. In the exemplary embodiment, the interconnection structure 106 includes a first surface 106-S1 and a second surface 106-S2 opposite to the first surface 106-S1. The first semiconductor die 110 and the second semiconductor die 112 are disposed on the first surface 106-S1 of the interconnection structure 106, while the second surface 106-S2 of the interconnection structure 106 is attached to the debond layer 104.

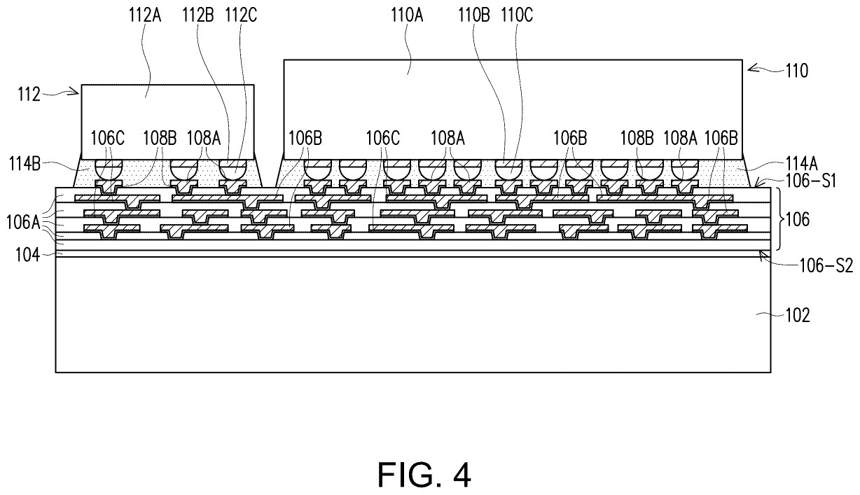

Referring to FIG. 4, in a subsequent step, an underfill structure 114A is formed between the first semiconductor die 110 and the interconnection structure 106 to cover and laterally surround the connecting pads 110B, the conductive bumps 110C and the bonding pads 108A. Similarly, an underfill structure 114B is formed between the second semiconductor die 112 and the interconnection structure 106 to cover and laterally surround the connecting pads 112B, the conductive bumps 112C and the bonding pads 108A. In some embodiments, the underfill structure 114A is partially covering sidewalls of the first semiconductor die 110, while the underfill structure 114B is partially covering sidewalls of the second semiconductor die 112. Furthermore, in some embodiments, the underfill structure 114A is physically separated from the underfill structure 114B.

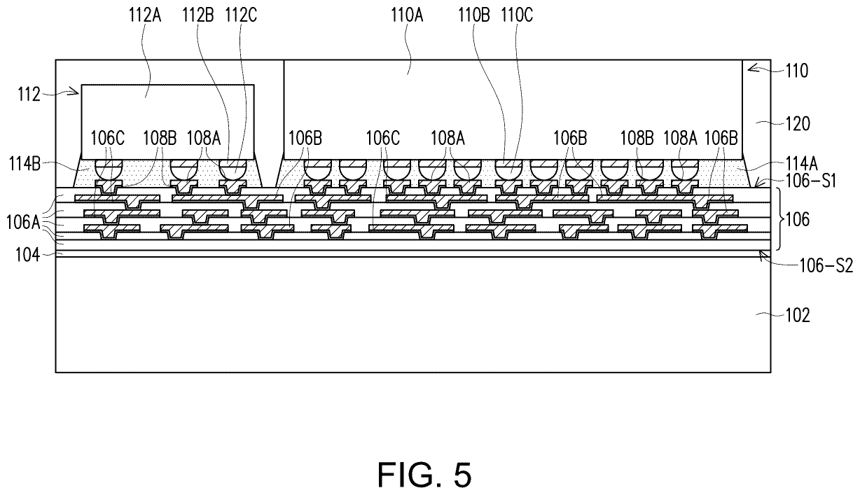

Referring to FIG. 5, in some embodiments, an insulating encapsulant 120 (or molding compound) may be formed over the interconnection structure 106 to cover the conductive bumps 110C, 112C, the underfill structures 114A, 114B, and to surround the first and second semiconductor dies 110, 112. In some embodiments, the insulating encapsulant 120 is formed through, for example, a compression molding process or transfer molding. In one embodiment, a curing process is performed to cure the insulating encapsulant 120. In some embodiments, a planarization or grinding process is performed on the insulating encapsulant 120. For example, after the planarization or grinding process, a backside surface of the first semiconductor die 110 is revealed by the insulating encapsulant 120, while a backside surface of the second semiconductor dies 112 is covered by the insulating encapsulant 120.

In some embodiments, a material of the insulating encapsulant 120 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 120 may include an acceptable insulating encapsulation material. In some embodiments, the insulating encapsulant 120 may further include inorganic filler or inorganic compound (e.g. silica, clay, and so on) which can be added therein to optimize coefficient of thermal expansion (CTE) of the insulating encapsulant 120. The disclosure is not limited thereto.

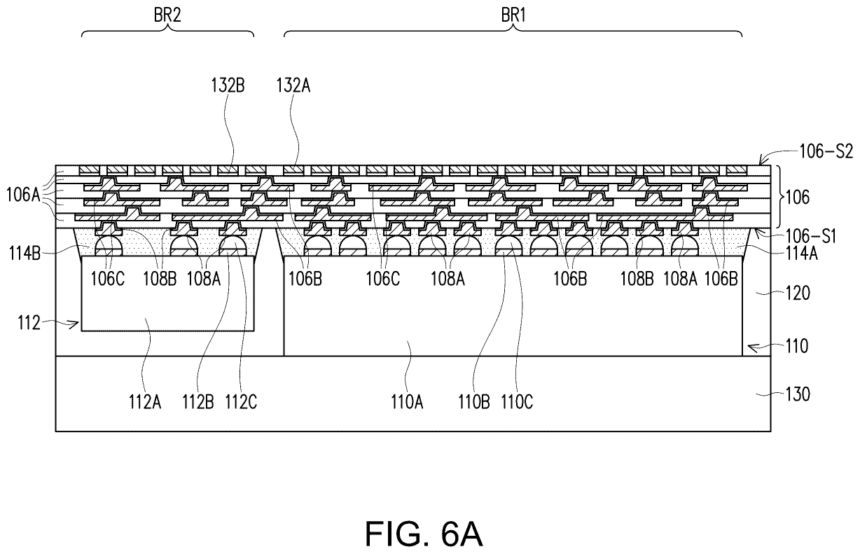

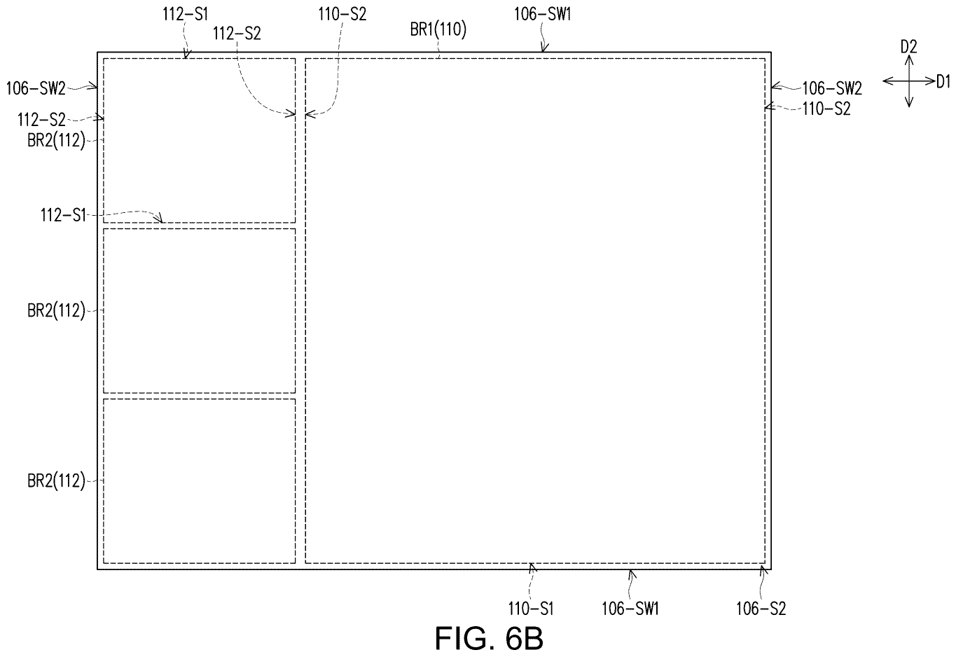

Referring to FIG. 6A, in a subsequent step, the structure shown in FIG. 5 is flipped and transferred onto another carrier 130, whereby the carrier 102 is debonded to reveal the second surface 106-S2 of the interconnection structure 106. For example, the de-bonding process includes projecting a light such as a laser light or an UV light on the debond layer 104 (e.g., the LTHC release layer) so that the carrier 102 can be easily removed along with the debond layer 104. In some embodiments, after removing the carrier 102 and the debond layer 104, the dielectric layer 106A on the second surface 106-S2 of the interconnection structure 106 is patterned to form openings. Thereafter, seed layers 132B and bonding pads 132A are formed to fill up the openings. In certain embodiments, the seed layers 132B and bonding pads 132A are electrically connected to the seed layers 106C and the conductive elements 106B located underneath. In some embodiments, materials of the seed layers 132B and the bonding pads 132A are similar to the materials of the seed layers 108B and the bonding pads 108A, thus their detailed description will be omitted herein. In certain embodiments, a top surface of the bonding pads 132A is revealed at the second surface 106-S2 of the interconnection structure 106, and is coplanar and aligned with a top surface of the dielectric layer 106A.

As further illustrated from a top view of the interconnection structure 106 shown in FIG. 6B, the second surface 106-S2 of the interconnection structure 106 includes a first bonding region BR1, and a plurality of second bonding regions BR2. In FIG. 6B, the bonding pads 132A revealed at the second surface 106-S2 of the interconnection structure 106 are omitted for ease of illustration. In some embodiments, the first bonding region BR1 corresponds to and overlaps with a region where the first semiconductor die 110 is located, while the second bonding regions BR2 corresponds to and overlaps with regions where the second semiconductor dies 112 are located. Referring to FIG. 6A and FIG. 6B, the first semiconductor die 110 in the first bonding region BR1 includes first sidewalls 110-S1 extending along a first direction D1, and second sidewalls 110-S2 extending along a second direction D2 that is perpendicular to the first direction D1. For example, the first sidewalls 110-S1 are joined with the second sidewalls 110-S2. Furthermore, the second semiconductor dies 112 in the second bonding regions BR2 includes first sidewalls 112-S1 extending along the first direction D1, and second sidewalls 112-S2 extending along the second direction D2. For example, the first sidewalls 112-S1 are joined with the second sidewalls 112-S2. Similarly, the interconnection structure 106 includes first sidewalls 106-SW1 extending along the first direction D1, and second sidewalls 106-SW2 extending along the second direction D2. In other words, the first sidewalls 106-SW1 of the interconnection structure 106 are parallel with the first sidewalls 110-S1 and the first sidewalls 112-S1, while the second sidewalls 106-SW2 are parallel with the second sidewalls 110-S2 and the second sidewalls 112-S2.

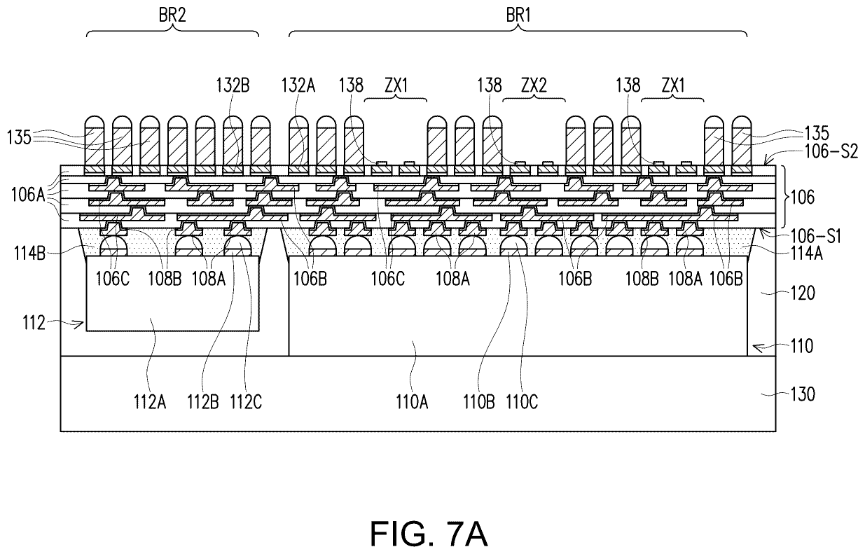

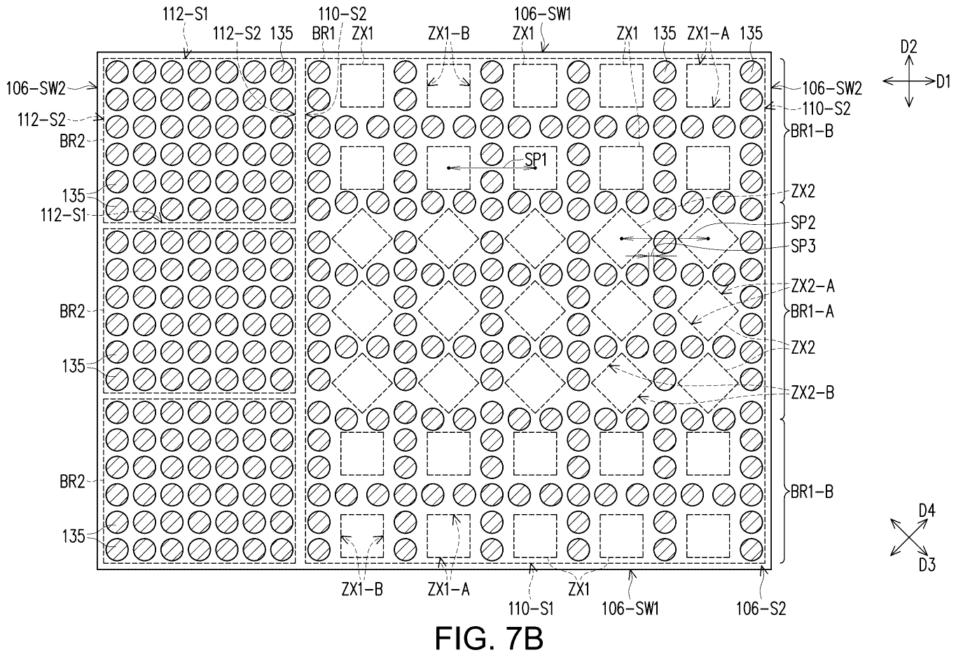

As illustrated in FIG. 7A and FIG. 7B, after forming the bonding pads 132A at the second surface 106-S2 of the interconnection structure 106, a plurality of bump structures 135 and a plurality of conductive pads 138 are formed on the interconnection structure 106 and electrically connected to the bonding pads 132A. In some embodiments, the bump structures 135 include lead-free solder balls, solder balls, ball grid array (BGA) balls, bumps, C4 bumps or micro bumps, and may include a conductive material such as solder, copper, aluminum, gold, nickel, silver, palladium, tin, or a combination thereof. In certain embodiments, the bump structures 135 includes metal pillars, and solders formed on the metal pillars. In some embodiments, the conductive pads 138 include a conductive material such as solder, copper, or the like.

In some embodiments, the bump structures 135 are arranged in the first bonding region BR1, so that the first bonding region BR1 includes a plurality of first bump-free zones ZX1 and a plurality of second bump-free zones ZX2 that are free of the bump structures 135. In other words, besides the first bump-free zones ZX1 and the second bump-free zones ZX2, the remaining area of the first bonding region BR1 are packed with the bump structures 135. The arrangement of the bump structures 135 shown in FIG. 7B are for illustrative purposes, and the bump structures 135 may in fact be densely packed in all areas outside of the first bump-free zones ZX1 and the second bump-free zones ZX2. In certain embodiments, the first bump-free zones ZX1 and the second bump-free zones ZX2 are keep-out zones (KOZ). In some embodiments, the conductive pads 138 are located in the first bump-free zones ZX1 and the second bump-free zones ZX2, and are used for providing electrical connection to passive devices disposed in a subsequent step. In some embodiments, the first bonding region BR1 includes a center region BR1-A and side regions BR1B located on two sides of the center region BR1-A, wherein the second bump-free zones ZX2 are located in the center region BR1-A, while the first bump-free zones ZX1 are located in the side regions BR1-B. In certain embodiments, the bump structures 135 are arranged in the second bonding regions BR2 so that there are no bump-free zones. In other words, the bump structures 135 are packed in the second bonding regions BR2 and electrically connected to the interconnect structure 106 located underneath.

In the illustrated embodiment, the first bump-free zones ZX1 are separated from one another and are arranged as an orthogonal grid pattern (e.g. 2×5 grid) in each of the side regions BR1-B. In some embodiments, each of the first bump-free zones ZX1 include first zone boundaries ZX1-A that are arranged in parallel with and extending along the first direction D1, and second zone boundaries ZX1-B that are arranged in parallel with and extending along the second direction D2. The first zone boundaries ZX1-A are joined with the second zone boundaries ZX1-B so that each of the first bump-free zones ZX1 have a quadrilateral shape.

Furthermore, in some embodiments, the second bump-free zones ZX2 are separated from one another and arranged in a different manner with the first bump-free zones ZX1 in the center region BR1-A. In some embodiments, the second bump-free zones ZX2 are arranged as a titled grid pattern (e.g. 3×5 grid) with each of the second bump-free zones ZX2 tilted at an angle. For example, each of the second bump-free zones ZX2 include third zone boundaries ZX2-A that are arranged in parallel with and extending along a third direction D3, and fourth zone boundaries ZX2-B that are arranged in parallel with and extending along a fourth direction D4 perpendicular to the third direction D3, wherein the third direction D3 and the fourth direction D4 are different from the first direction D1 and the second direction D2. In some embodiments, the third zone boundaries ZX2-A are joined with the fourth zone boundaries ZX2-B so that each of the second bump-free zones ZX2 have a quadrilateral shape. However, the quadrilateral shape of the second bump-free zones ZX2 is tilted at an angle (not 90°) relative to the quadrilateral shape of the first bump-free zones ZX1.

In the exemplary embodiment, the first bump-free zones ZX1 are separated from one another by a first spacing SP1 and the second bump-free zones ZX2 are separated from one another by a second spacing SP2, while the bump structures 135 are disposed in the first bonding region BR1 with a third spacing SP3. The first spacing SP1 is measured from a center of one of the first bump-free zones ZX1 to a center of an adjacent first bump-free zone ZX1. Similarly, the second spacing SP2 is measured from a center of one of the second bump-free zones ZX2 to a center of an adjacent second bump-free zone ZX2. The third spacing SP3 is measured from side surfaces of one of the bump structures 135 to the side surfaces of an adjacent bump structure 135. As illustrated in FIG. 7B, the first spacing SP1 is substantially equal to the second spacing SP2, while the first spacing SP1 and the second spacing SP2 are greater than the third spacing SP3.

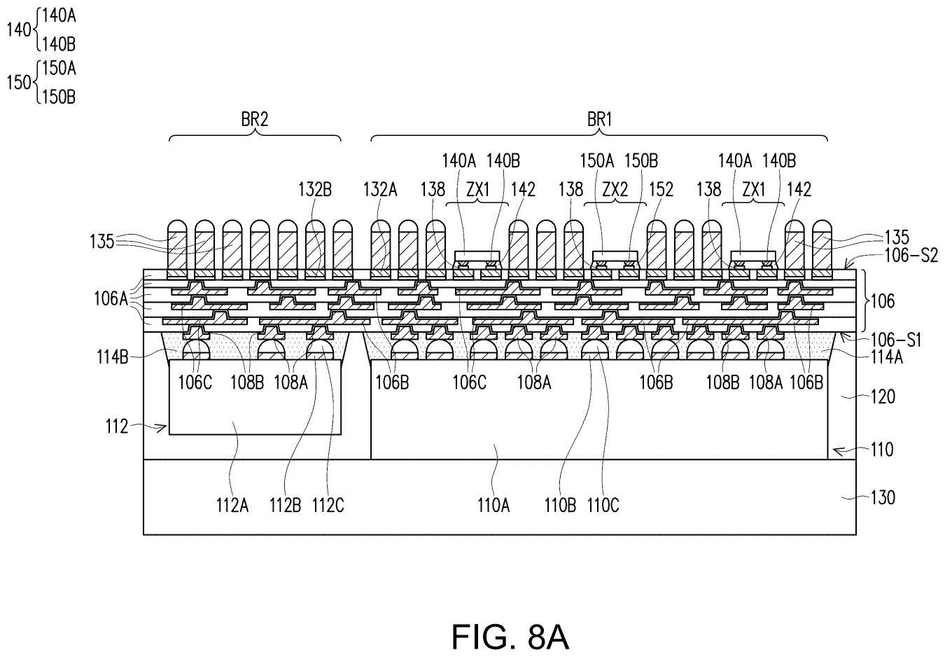

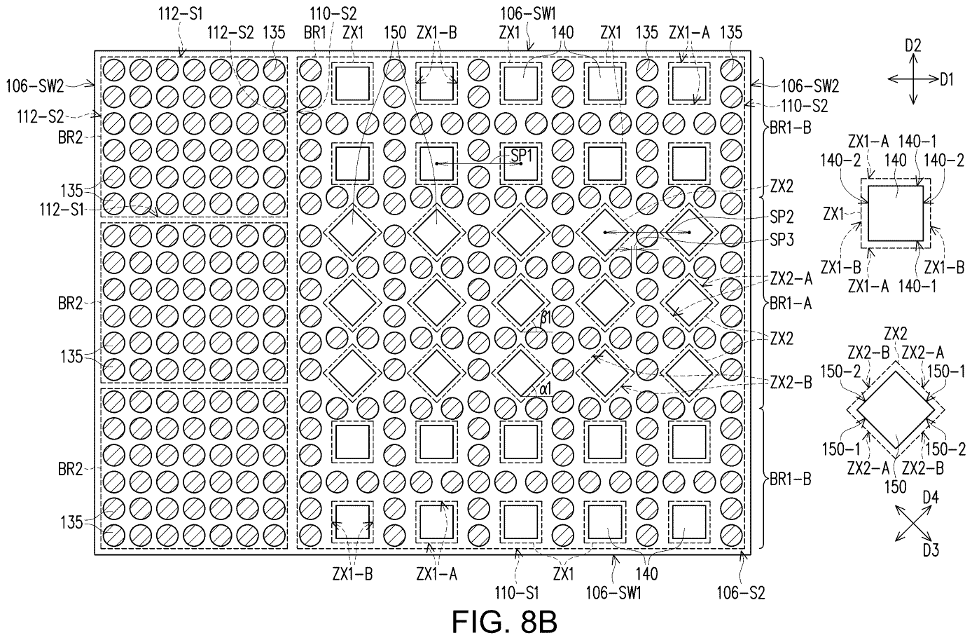

Referring to FIG. 8A and FIG. 8B, in a subsequent step, a plurality of passive devices including first passive devices 140 and second passive devices 150 are respectively disposed in the first bump-free zones ZX1 and the second bump-free zones ZX2. In some embodiments, the first passive devices 140 includes a core portion 140A and a plurality of conductive bumps 140B disposed on the core portion 140A, wherein the conductive bumps 140B are electrically connecting the first passive devices 140 to the conductive pads 138. Furthermore, the second passive devices 150 includes a core portion 150A and a plurality of conductive bumps 150B disposed on the core portion 150A, wherein the conductive bumps 150B are electrically connecting the second passive devices 150 to the conductive pads 138. In some embodiments, an underfill structure 142 is filled in between the first passive devices 140 and the interconnection structure 106 to cover and surround the conductive bumps 140B and the conductive pads 138. Similarly, an underfill structure 152 is filled in between the second passive devices 150 and the interconnection structure 106 to cover and surround the conductive bumps 150B and the conductive pads 138.

As illustrated in FIG. 8B, the first passive devices 140 are disposed in the first bump-free zones ZX1, and are electrically connected to the interconnection structure 106 and arranged as a first pattern. The second passive devices 150 are disposed in the second bump-free zones ZX2, and are electrically connected to the interconnection structure 106 and arranged as a second pattern, wherein the second pattern is different from the first pattern. For example, in the exemplary embodiment, the first passive devices 140 are arranged as an orthogonal grid pattern (e.g. 2×5 grid) in each of the side regions BR1-B, whereas the second passive devices 150 are arranged to have a tilted pattern in the center region BR1-A of the first bonding region BR1. In some embodiments, the bump structures 135 are laterally surrounding the first passive devices 140 and the second passive devices 150. In certain embodiments, the second bonding regions BR2 are free of any passive devices.

In the exemplary embodiment, from the top view of the first bonding region BR1 at the second surface 106-S2 of the interconnection structure 106 shown in FIG. 8B, an area occupied by each of the first bump-free zones ZX1 is greater than an area occupied by each of the first passive devices 140, and an area occupied by each of the second bump-free zones ZX2 is greater than an area occupied by each of the second passive devices 150. In some embodiments, the first passive devices 140 includes first sidewalls 140-1 extending along the first direction D1 and second sidewalls 140-2 extending along the second direction D2. For example, the first sidewalls 140-1 of the first passive devices 140 are arranged to be in parallel with the first zone boundaries ZX1-A, whereas the second sidewalls 140-2 of the first passive devices 140 are arranged to be in parallel with the second zone boundaries ZX1-B.

In some embodiments, the second passive devices 150 includes first sidewalls 150-1 extending along the third direction D3 and second sidewalls 140-2 extending along the fourth direction D4. For example, the first sidewalls 150-1 of the second passive devices 150 are arranged to be in parallel with the third zone boundaries ZX2-A, whereas the second sidewalls 150-2 of the second passive devices 150 are arranged to be in parallel with the fourth zone boundaries ZX2-B. In the exemplary embodiment, the second sidewalls 150-2 of the second passive devices 150 are tilted at an angle α1 relative to first sidewalls 106-SW1 of the interconnection structure 106, wherein the angle α1 is not 90°. Similarly, the fourth zone boundaries ZX2-B are tilted at an angle β1 relative to first sidewalls 106-SW1 of the interconnection structure 106, wherein the angle β1 is not 90°. In some embodiments the angle α1 and the angle β1 are respectively 5°, 10°, 15°, 20°, 25°, 30°, 35°, 40°, 45°, 50°, 55°, 60°, 65°, 70°, 75°, 80° or 85°. In certain embodiments, the angle α1 and the angle β1 are appropriately adjusted as long as the angle is not 90°, and are tilted relative to the first sidewalls 106-SW1 of the interconnection structure 106, or tilted relative to the first sidewalls 110-S1 of the first semiconductor die 110.

As further illustrated in FIG. 8B, the first passive devices 140 are arranged in a plurality of columns and a plurality of rows in the side regions BR1-B (e.g. 5 columns and 2 rows) of the first bonding region BR1. For example, the first sidewalls 140-1 and second sidewalls 140-2 of one of the first passive devices 140 arranged in one of the columns and one of the rows are aligned with the first sidewalls 140-1 and second sidewalls 140-2 of another first passive device 140 arranged in a subsequent column or in a subsequent row. Furthermore, the second passive devices 150 are arranged in a plurality of columns and a plurality of rows in the center region BR1-A (e.g. 5 columns and 3 rows) of the first bonding region BR1. For example, the first sidewalls 150-1 and second sidewalls 150-2 of one of the second passive devices 150 arranged in one of the columns and one of the rows are misaligned with the first sidewalls 150-1 and second sidewalls 150-2 of another second passive device 150 arranged in a subsequent column or in a subsequent row.

The number (N1) of first passive devices 140 and the number (N2) of second passive devices 150 shown in FIG. 8B are for illustrative purposes, and these numbers may be adjusted based on actual product requirements. In some embodiments, a ratio (N2/(N1+N2) of a number of the second passive devices 150 relative to a total number of the first passive devices 140 and the second passive devices 150 is in a range of 1% to 60%. In certain embodiments, the ratio (N2/(N1+N2) is in a range of 1% to 50%, in a range of 1% to 40%, in a range of 1% to 30% in a range of 1% to 20%, or in a range of 1% to 10%.

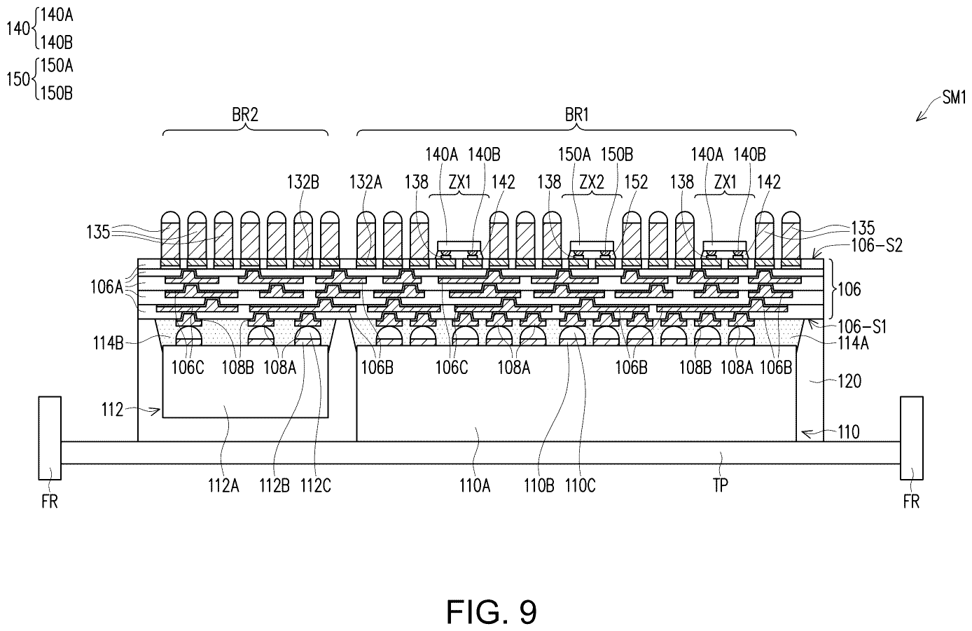

Referring to FIG. 9, after placing the first passive devices 140 and the second passive devices on the interconnection structure 106, the carrier 130 is debonded and then mounted onto a tape TP supported by a frame FR. A singulation process is then performed onto the resulted structure so as to form a plurality of semiconductor packages SM1. For example, a saw or other cutting device separates the individual units of the semiconductor packages SM1 along scribe lines (not shown).

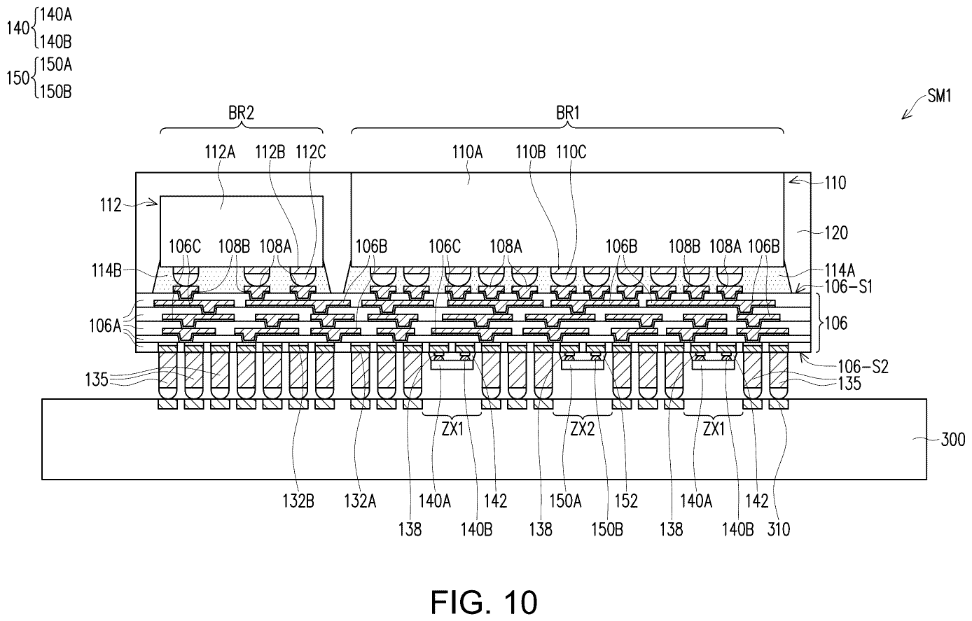

Referring to FIG. 10, in some embodiments, the semiconductor package SM1 shown in FIG. 9 is then mounted or attached onto a circuit substrate 300 through the bump structures 135. In other words, the first passive devices 140, the second passive devices, and the bump structures 135 are located in between the interconnection structure 106 and the circuit substrate 300. In some embodiments, the circuit substrate 300 is such as an organic flexible substrate or a printed circuit board. In some embodiments, the circuit substrate 300 includes contact pads 310, wherein the semiconductor package SM1 is bonded to the circuit substrate 300 by joining the bump structures 135 to the contact pads 310.

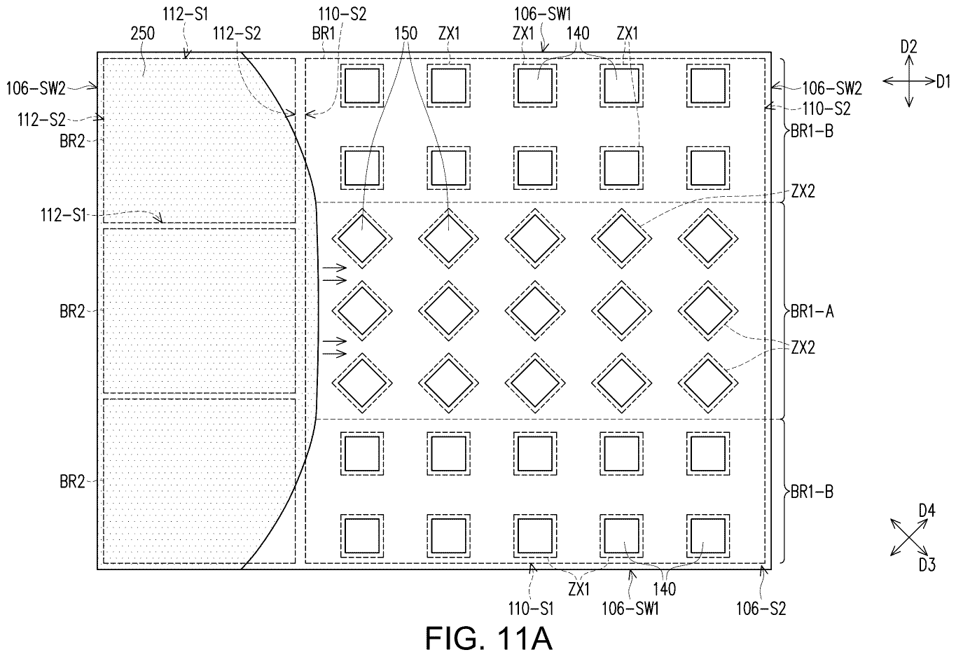

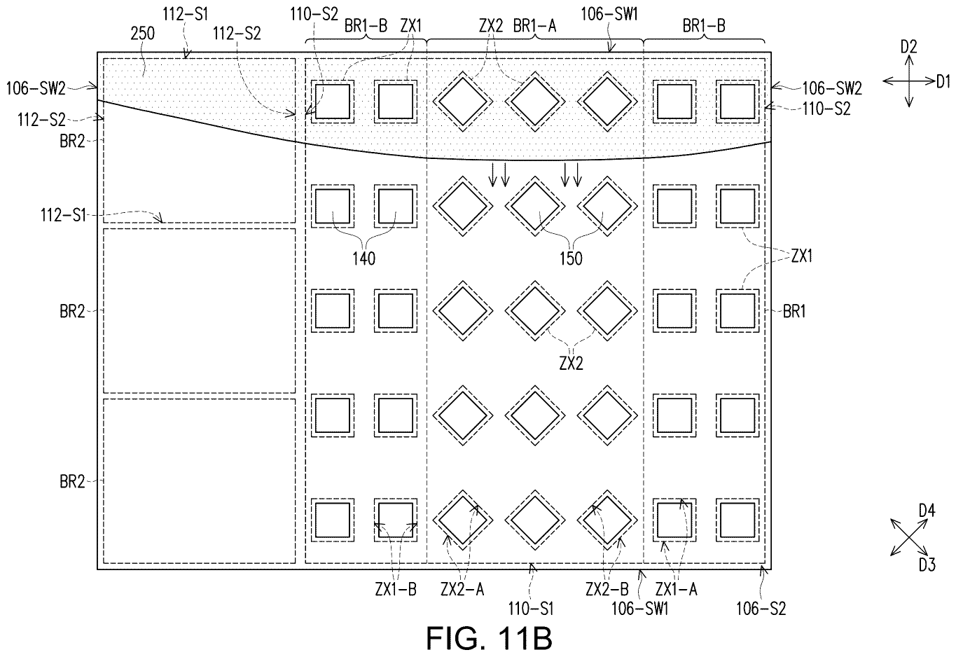

Referring to FIG. 11A, which is a top view from the second surface 106-S2 of the interconnection structure 106, an underfill structure 250 is formed to fill in a space in between the circuit substrate 300 and the interconnection structure 106 along the first direction D1. The bump structures 135 are omitted from FIG. 11A for ease of illustration. In the exemplary embodiment, when the underfill structure 250 is filled along the first direction D1, due to the fluid dynamics of the underfill material, the underfill structure 250 will first contact and cover the second passive devices 150 in the second bump-free zones ZX2 prior to contacting and covering the first passive devices 140. As such, the sidewalls (150-1, 150-2) of the second passive devices 150 are arranged at an angle relative to a contacting surface of the underfill structure 250. Similarly, due to a delayed flow of the underfill structure 250 to the side regions BR1-B, the contacting surface of the underfill structure 250 will be arranged at an angle relative to the sidewalls (140-1, 140-2) of the first passive devices 140. As such, the risk of forming voids during the filling of the underfill structure 250 can be reduced, and an underfill crack issue can be resolved.

FIG. 11B is an alternative embodiment of filling an underfill structure 250 in a space between the circuit substrate 300 and the interconnection structure 106. The bump structures 135 are omitted from FIG. 11B for ease of illustration. Referring to FIG. 11B, in some embodiments, the filling of the underfill structure 250 is not necessarily performed along the first direction D1, and may be filled along the second direction D2 or along another direction. Under such circumstances, the positions of the first passive devices 140 in the first bump-free zones ZX1, and the second passive devices 150 in the second bump-free zones ZX2 are rearranged so that underfill structure 250 will still be first contacting and covering the second passive devices 150 (the titled passive devices) in the second bump-free zones ZX2 prior to contacting and covering the first passive devices 140. In other words, the positions of the first passive devices 140 in the first bump-free zones ZX1, and the second passive devices 150 in the second bump-free zones ZX2 may be rearranged based on a filling direction of the underfill structure 250.

As illustrated in FIG. 11B, due to the fluid dynamics of the underfill material, the underfill structure 250 flowing along the second direction D2 will first contact and cover the second passive devices 150 in the second bump-free zones ZX2 prior to contacting and covering the first passive devices 140 in the same row. As such, the sidewalls (150-1, 150-2) of the second passive devices 150 are arranged at an angle relative to a contacting surface of the underfill structure 250. Similarly, due to a delayed flow of the underfill structure 250 to the side regions BR1-B along the second direction D2, the contacting surface of the underfill structure 250 will be arranged at an angle relative to the sidewalls (140-1, 140-2) of the first passive devices 140. As such, the risk of forming voids during the filling of the underfill structure 250 can be reduced, and an underfill crack issue can be resolved.

In some embodiments, with the increasing requirements of using underfills that fulfills the green material policy in various countries, a material of the underfill structure 250 is usually free of per-and polyfluorinated alkyl substances (PFAS). In certain embodiments, a material of the underfill structure 250 of the present disclosure includes SiO₂ and/or epoxy resins, but are free of PFAS materials. The PFAS-free underfills usually have reduced flowability, and have a higher risk of causing voids. By arranging the first passive devices 140 and the second passive devices 150 in the manner as described in the embodiments of the present disclosure, the formation of voids is greatly reduced even when PFAS-free underfills are used.

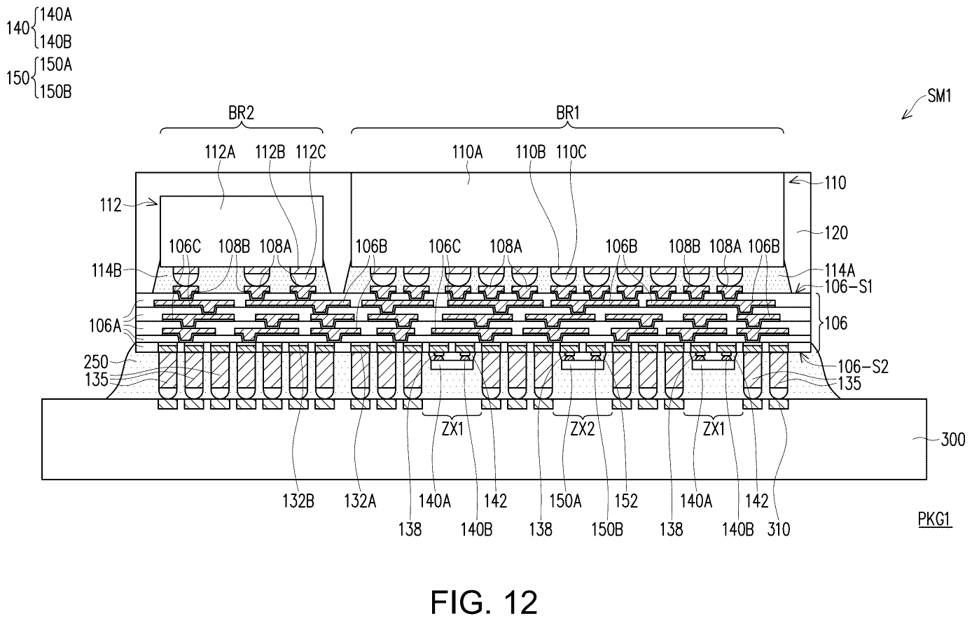

Referring to FIG. 12, in some embodiments, the underfill structure 250 is formed to cover and contact the first passive devices 140, the second passive devices 150 and the bump structures 135, and is filling up a space between the circuit substrate 300 and the interconnection structure 106. For example, the underfill structure 250 is physically contacting and laterally surrounding first passive devices 140, the second passive devices 150 and the bump structures 135, and partially contacting sidewalls of the interconnection structure 106. After forming the underfill structure 250, a package structure PKG1 in accordance with some embodiments of the present disclosure is accomplished. In the package structure PKG1, since the second passive devices 150 are arranged to be tilted at an angle relative to sidewalls of the interconnection structure 106, the risk of forming voids during the filling of the underfill structure 250 can be reduced, and an underfill crack issue can be resolved.

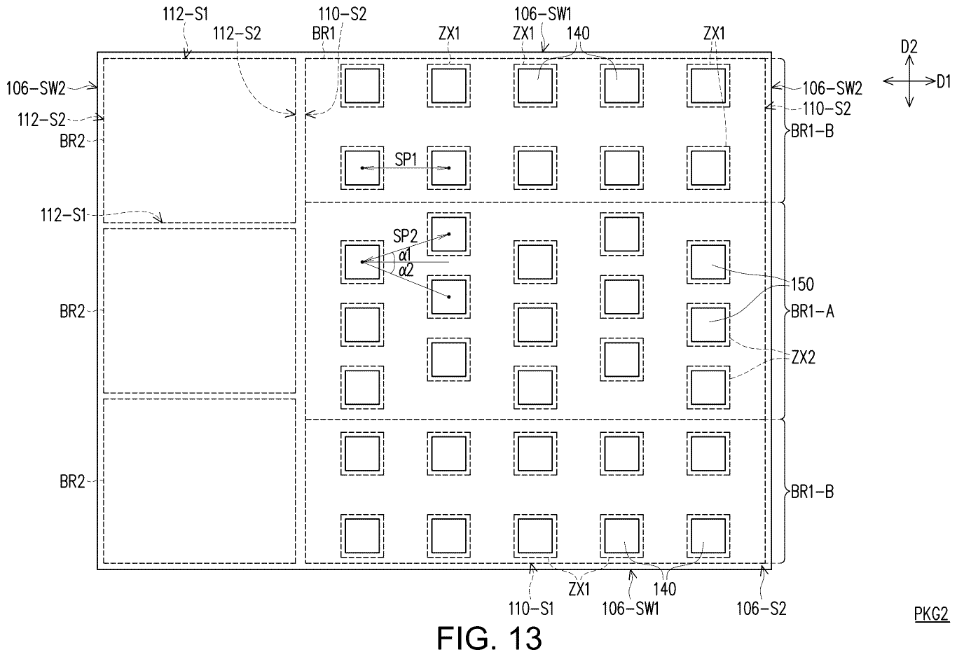

FIG. 13 is a schematic top view from a second surface 106-S2 of an interconnection structure 106 in a package structure PKG2 according to some exemplary embodiments of the present disclosure. The package structure PKG2 illustrated in FIG. 13 is similar to the package structure PKG1 illustrated in FIG. 12, and is fabricated using a similar method as described in FIG. 1 to FIG. 12. Therefore, the same reference numerals are used to refer to the same or like parts, and its detailed description will be omitted herein. The difference between the embodiments is in the arrangement of the second passive devices 150 in the center region BR1-A of the first bonding region BR1.

In the top view of the package structure PKG2 illustrated in FIG. 13, the bump structures 135 are omitted for ease of illustration. Furthermore, it should be noted that other components shown in the package structure PKG1 of FIG. 12 should also be similarly present in the package structure PKG2 of FIG. 13. Referring to FIG. 13, the first passive devices 140 are arranged in the side regions BR1-B of the first bonding region BR1 in a manner similar to that shown in FIG. 12. Furthermore, the second passive devices 150 are arranged in the center region BR1-A with a pattern different from that of the first passive devices 140. For example, in the exemplary embodiment, the second bump-free zones ZX2 and the second passive devices 150 are arranged in the center region BR1-A with a staggered pattern.

In some embodiments, a center position of one of the second passive devices 150 arranged in a first column is arranged at an angle of α1 relative to a center position of another second passive device 150 in a second column, and arranged at an angle of α2 relative to a center position of yet another second passive device 150 in the second column. The angle α1 and the angle α2 may be the same, or may be different. In other words, the second passive devices 150 arranged in the first column is misaligned with the second passive devices 150 arranged in the second column. In the exemplar embodiment, the second passive devices 150 arranged in the odd number columns are aligned with one another along the first direction D1, while the second passive devices 150 arranged in the even number columns are aligned with one another along the first direction D1. Furthermore, the second passive devices 150 arranged in the odd number columns and arranged in the even number columns are misaligned (or arranged at an angle) with one another.

In the package structure PKG2, since the second passive devices 150 are arranged to have a staggered pattern, the flow of the underfill structure 250 across from the second passive devices 150 in one column to the second passive devices 150 in a subsequent column will be arranged at an angle, thus the risk of forming voids/air traps during the filling of the underfill structure 250 can be reduced, and an underfill crack issue can be resolved. Overall, the yield and reliability of the package structure PKG2 are enhanced.

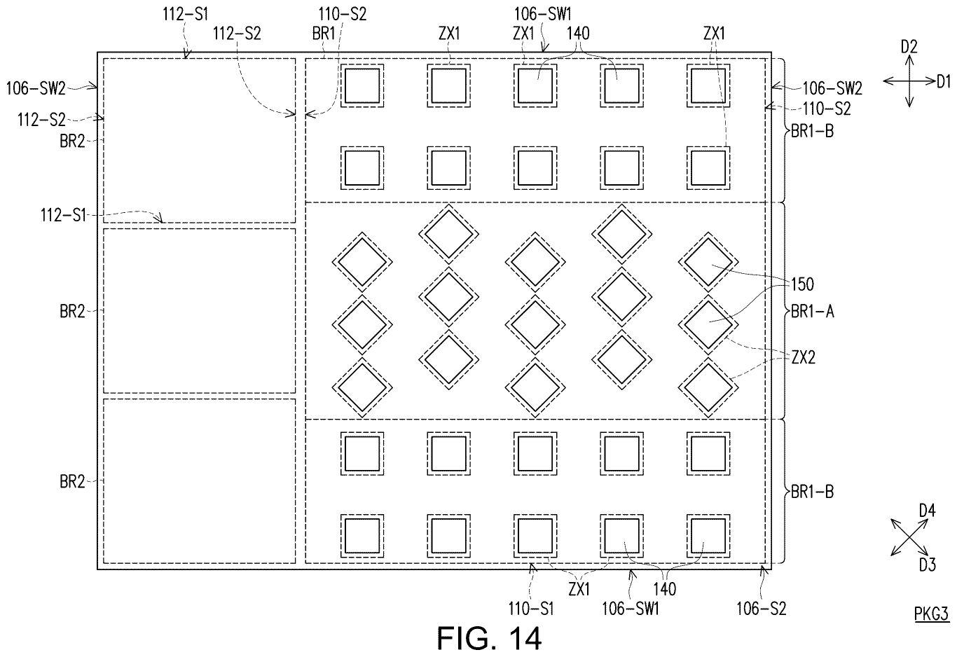

FIG. 14 is a schematic top view from a second surface of an interconnection structure in a package structure according to some other exemplary embodiments of the present disclosure. The package structure PKG3 illustrated in FIG. 14 is similar to the package structure PKG1 illustrated in FIG. 12, and is fabricated using a similar method as described in FIG. 1 to FIG. 12. Therefore, the same reference numerals are used to refer to the same or like parts, and its detailed description will be omitted herein. The difference between the embodiments is in the arrangement of the second passive devices 150 in the center region BR1-A of the first bonding region BR1.

In the top view of the package structure PKG3 illustrated in FIG. 14, the bump structures 135 are omitted for ease of illustration. Furthermore, it should be noted that other components shown in the package structure PKG1 of FIG. 12 should also be similarly present in the package structure PKG3 of FIG. 14. Referring to FIG. 14, the first passive devices 140 are arranged in the side regions BR1-B of the first bonding region BR1 in a manner similar to that shown in FIG. 12. Furthermore, the second passive devices 150 are arranged in the center region BR1-A with a staggered and tilted pattern. In other words, first and second sidewalls (150-1, 150-2) of the second passive devices 150 are tilted at an angle relative to the first sidewalls 106-SW1 of the interconnection structure 106, and the angle is not 90°. Furthermore, the second passive devices 150 arranged in the odd number columns and arranged in the even number columns are misaligned (or arranged at an angle) with one another.

In the package structure PKG3, since the second passive devices 150 are arranged to be tilted at an angle relative to sidewalls of the interconnection structure 106 and arranged to have a staggered pattern, the flow of the underfill structure 250 across from the second passive devices 150 in one column to the second passive devices 150 in a subsequent column will be arranged at an angle. As such, the risk of forming voids/air traps during the filling of the underfill structure 250 can be reduced, and an underfill crack issue can be resolved. Overall, the yield and reliability of the package structure PKG3 are enhanced.

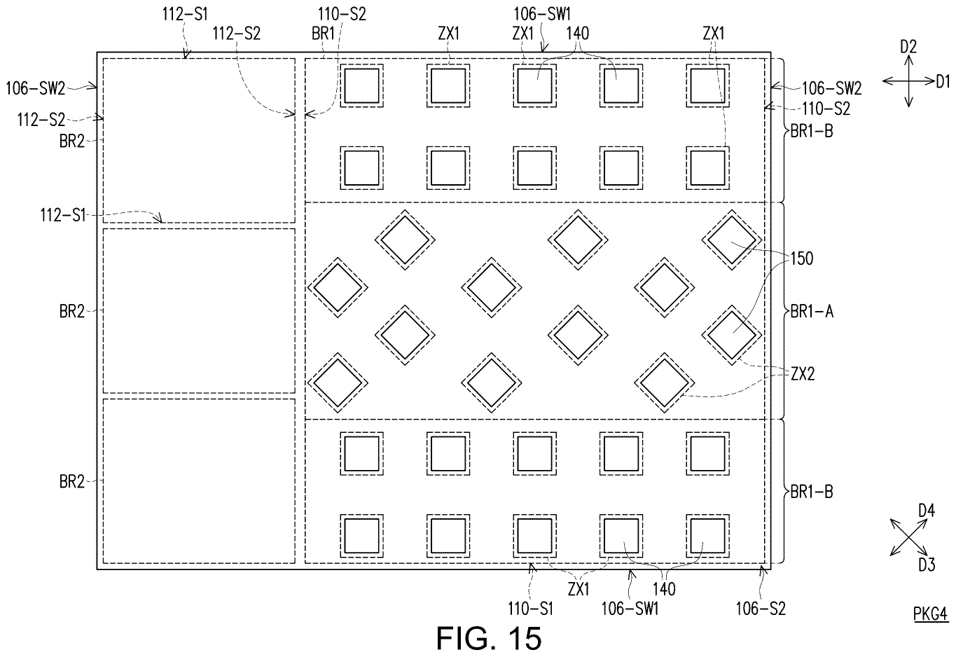

FIG. 15 is a schematic top view from a second surface of an interconnection structure in a package structure according to some other exemplary embodiments of the present disclosure. The package structure PKG4 illustrated in FIG. 15 is similar to the package structure PKG3 illustrated in FIG. 14. Therefore, the same reference numerals are used to refer to the same or liked parts, and its detailed description will be omitted herein. The difference between the embodiments is in the arrangement of the second passive devices 150 in the center region BR1-A of the first bonding region BR1.

In FIG. 14, a center position of the second passive devices 150 are arranged to be aligned with a center position of the first passive devices 140 along the second direction D2 in the same column. However, the disclosure is not limited thereto. For example, as illustrated in FIG. 15, a center position of the second passive devices 150 are arranged to be misaligned with a center position of the first passive devices 140 along the second direction D2. A number of columns of the second passive devices 150 may also be different to a number of columns of the first passive devices 140.

In the package structure PKG4, since the second passive devices 150 are arranged to be tilted at an angle relative to sidewalls of the interconnection structure 106 and arranged to have a staggered pattern, the flow of the underfill structure 250 across from the second passive devices 150 in one column to the second passive devices 150 in a subsequent column will be arranged at an angle. As such, the risk of forming voids/air traps during the filling of the underfill structure 250 can be reduced, and an underfill crack issue can be resolved. Overall, the yield and reliability of the package structure PKG4 are enhanced.

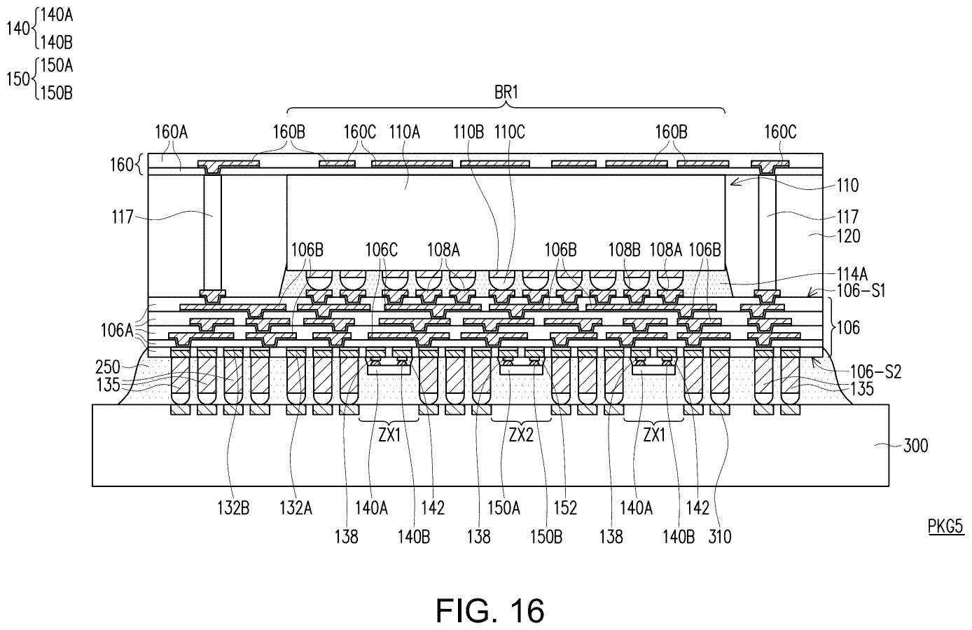

FIG. 16 is a schematic sectional view of a package structure according to some other exemplary embodiments of the present disclosure. The package structure PKG5 illustrated in FIG. 16 is similar to the package structure PKG1 illustrated in FIG. 12. Therefore, the same reference numerals are used to refer to the same or liked parts, and its detailed description will be omitted herein.

Referring to FIG. 16, in the package structure PKG5, the first passive devices 140, the second passive devices 150, the bump structures 135 and the underfill structure 250 are arranged in between the interconnection structure 106 and the circuit substrate 300 in a similar manner to that of FIG. 12. In some embodiments, the first semiconductor die 110 is disposed on and bonded to a first bonding region BR1 of the interconnection structure 106, and are overlapped with the first passive devices 140 in the first bump-free zones ZX1, and overlapped with the second passive devices 150 in the second bump-free zones ZX2. Furthermore, remaining regions of the interconnection structure 106 other than the first bonding region BR1 shown in FIG. 16, may be in a similar arrangement to the second bonding regions BR2 shown in FIG. 12.

In some embodiments, a plurality of through insulator vias 117 is formed to surround the first semiconductor die 110, and formed to be electrically connected to the interconnection structure 106. In some embodiments, the through insulator vias 117 are through integrated fan-out (“InFO”) vias. In one embodiment, the formation of the through insulator vias 117 includes forming a mask pattern (not shown) with openings, then forming a metallic material (not shown) filling up the openings by electroplating or deposition, and removing the mask pattern to form the through insulator vias 117 on the interconnection structure 106. In certain embodiments, the through insulator vias 117 are formed to be electrically connected to the bonding pads 108A of the interconnection structure 106. In some embodiments, the material of the mask pattern may include a positive photo-resist or a negative photo-resist. In one embodiment, the material of the through insulator vias 117 may include a metal material such as copper or copper alloys, or the like. However, the disclosure is not limited thereto.

As further illustrated in FIG. 16, the insulating encapsulant 120 (or molding compound) is formed to encapsulate the first semiconductor die 110 and the through insulator vias 117. Furthermore, a redistribution layer 160 is formed on the insulating encapsulant 120 on backsides of the first semiconductor die 110, wherein the redistribution layer 160 is electrically connected to the through insulator vias 117. In some embodiments, forming the redistribution layer 160 includes forming a plurality of dielectric layers 160A, a plurality of conductive elements 160B, and a plurality of seed layers 160C alternately stacked up along a build-up direction. The number of layers of the dielectric layers 160A, the number of layers of the conductive elements 160B, and the number of layers of the seed layers 160C are not particularly limited, and may be adjusted based on product requirement.

In the package structure PKG5 illustrated in FIG. 16, since the second passive devices 150 are arranged to have a different pattern (e.g. tilted and/or staggered in the manner shown in FIG. 11A, FIG. 13 to FIG. 15) relative to the first passive devices 140, the risk of forming voids/air traps during the filling of the underfill structure 250 can be reduced, and an underfill crack issue can be resolved. Overall, the yield and reliability of the package structure PKG5 are enhanced.

In the above embodiments, the package structure includes first passive devices and second passive devices electrically connected to the interconnection structure, and bump structures laterally surrounding the first passive devices and the second passive devices. Since the second passive devices are arranged on the interconnection with a different pattern (tilted and/or staggered) than the first passive devices, an underfill flow rate/fluid dynamics may be appropriately controlled to avoid the formation of voids. In other words, the risk of forming voids/air traps during the filling of the underfill structure can be reduced, and an underfill crack issue can be resolved. Overall, the yield and reliability of the package structure are enhanced. Furthermore, environmentally friendly underfill materials having reduced flowability may also be used in the package structure with a lower risk of forming voids.

In accordance with some embodiments of the present disclosure, a package structure includes a circuit substrate and a semiconductor package disposed on and electrically connected to the circuit substrate. The semiconductor package includes and interconnection structure, first passive devices, second passive devices and bump structures. The first passive devices are electrically connected to the interconnection structure, and arranged as a first pattern in between the interconnection structure and the circuit substrate. The second passive devices are electrically connected to the interconnection structure, and arranged as a second pattern in between the interconnection structure and the circuit substrate, wherein the second pattern is different from the first pattern. The bump structures are electrically connecting the interconnection structure to the circuit substrate and laterally surrounding the first passive devices and the second passive devices.

In accordance with some other embodiments of the present disclosure, a package structure includes an interconnection structure, a semiconductor die, a plurality of bump structures, and a plurality of passive devices. The interconnection structure includes a first surface and a second surface opposite to the first surface, wherein the second surface includes a first bonding region. The semiconductor die is disposed on the first surface of the interconnection structure overlapped with the first bonding region, and electrically connected to the interconnection structure, wherein the semiconductor die includes first sidewalls extending along a first direction, and second sidewalls extending along a second direction perpendicular to the first direction. The bump structures are disposed on the second surface of the interconnection structure in the first bonding region, and electrically connected to the interconnection structure. The first bonding region includes a plurality of first bump-free zones and a plurality of second bump-free zones that are free of the bump structures, the first bump-free zones are separated from one another and arranged as an orthogonal grid pattern, and each of the first bump-free zones include first zone boundaries that are arranged in parallel with and extending along the first direction, and second zone boundaries that are arranged in parallel with and extending along the second direction. The second bump-free zones are separated from one another and arranged in a different manner with the first bump-free zone. The passive devices are disposed in the plurality of first bump-free zones and the plurality of second bump-free zones.

In accordance with yet another embodiment of the present disclosure, a method of fabricating a package structure includes the follow steps. A semiconductor package is formed by: forming an interconnection structure; electrically connecting a plurality of first passive devices to the interconnection structure, wherein the first passive devices are arranged as a first pattern on the interconnection structure; electrically connecting a plurality of second passive devices to the interconnection structure, wherein the second passive devices are arranged as a second pattern on the interconnection structure, and the second pattern is different from the first pattern; and electrically connecting a plurality of bump structures to the interconnection structure, wherein the bump structures are laterally surrounding the first passive devices and the second passive devices. The semiconductor package is bonded to a circuit substrate, so that the semiconductor package is electrically connected to the circuit substrate, and wherein the first passive devices arranged and the second passive devices are located in between the interconnection structure and the circuit substrate, and the bump structures are electrically connecting the interconnection structure to the circuit substrate.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A package structure, comprising:
a circuit substrate;
a semiconductor package disposed on and electrically connected to the circuit substrate, wherein the semiconductor package comprises:
an interconnection structure;
a plurality of first passive devices electrically connected to the interconnection structure, and arranged as a first pattern in between the interconnection structure and the circuit substrate;
a plurality of second passive devices electrically connected to the interconnection structure, and arranged as a second pattern in between the interconnection structure and the circuit substrate, wherein the second pattern is different from the first pattern; and
a plurality of bump structures electrically connecting the interconnection structure to the circuit substrate and laterally surrounding the plurality of first passive devices and the plurality of second passive devices.

2. The package structure according to claim 1, wherein the plurality of first passive devices is arranged as an orthogonal grid pattern in between the interconnection structure and the circuit substrate.

3. The package structure according to claim 1, wherein the plurality of second passive devices is arranged as a staggered pattern in between the interconnection structure and the circuit substrate.

4. The package structure according to claim 3, wherein a ratio of a number of the plurality of second passive devices relative to a total number of the plurality of first passive devices and the plurality of second passive devices is in a range of 1% to 60%.

5. The package structure according to claim 1, wherein the plurality of second passive devices is arranged to have a tilted pattern, whereby sidewalls of the plurality of second passive devices are tilted at an angle relative to a sidewall of the interconnection structure, and the angle is not 90°.

6. The package structure according to claim 1, wherein the plurality of second passive devices arranged as the second pattern are arranged in a plurality of columns and a plurality of rows, wherein sidewalls of the plurality of second passive devices arranged in one column of the plurality of columns is misaligned with sidewalls of the plurality of second passive devices arranged in a subsequent column of the plurality of columns.

7. The package structure according to claim 1, further comprising an underfill structure covering and contacting the plurality of first passive devices, the plurality of second passive devices and the plurality of bump structures.

8. A package structure, comprising:
an interconnection structure, comprising a first surface and a second surface opposite to the first surface, wherein the second surface includes a first bonding region;
a semiconductor die disposed on the first surface of the interconnection structure overlapped with the first bonding region, and electrically connected to the interconnection structure, wherein the semiconductor die includes first sidewalls extending along a first direction, and second sidewalls extending along a second direction perpendicular to the first direction;
a plurality of bump structures disposed on the second surface of the interconnection structure in the first bonding region, and electrically connected to the interconnection structure,
wherein the first bonding region includes a plurality of first bump-free zones and a plurality of second bump-free zones that are free of the plurality of bump structures, the plurality of first bump-free zones is separated from one another and arranged as an orthogonal grid pattern, and each of the plurality of the first bump-free zones include first zone boundaries that are arranged in parallel with and extending along the first direction, and second zone boundaries that are arranged in parallel with and extending along the second direction, and
the plurality of second bump-free zones is separated from one another and arranged in a different manner with the plurality of first bump-free zones;
a plurality of passive devices disposed in the plurality of first bump-free zones and the plurality of second bump-free zones.

9. The package structure according to claim 8, wherein from a top view of the first bonding region at the second surface of the interconnection structure, an area occupied by each of the plurality of first bump-free zones is greater than an area occupied by each of the plurality of passive devices, and an area occupied by each of the plurality of second bump-free zones is greater than the area occupied by each of the plurality of passive devices.

10. The package structure according to claim 8, wherein the plurality of first bump-free zones is separated from one another by a first spacing, the plurality of second bump-free zones is separated from one another by a second spacing, and the plurality of bump structures is disposed in the first bonding region with a third spacing, wherein the first spacing and the second spacing are greater than the third spacing.

11. The package structure according to claim 8, wherein the plurality of second bump-free zones is arranged as a staggered pattern.

12. The package structure according to claim 8, wherein each of the plurality of second bump-free zones include third zone boundaries that are arranged in parallel with and extending along a third direction, and fourth zone boundaries that are arranged in parallel with and extending along a fourth direction perpendicular to the third direction, wherein the third direction and the fourth direction are different from the first direction and the second direction.

13. The package structure according to claim 8, wherein the first bonding region includes a center region and side regions located on two sides of the center region, and wherein the plurality of second bump-free zones is located in the center region, and the plurality of first bump-free zones is located in the side regions.

14. The package structure according to claim 8, wherein the second surface of the interconnection structure further comprises a plurality of second bonding regions, and the plurality of bump structures is further disposed on the second surface of the interconnection structure in the plurality of second bonding regions, and the plurality of second bonding regions is free of passive devices, and wherein the package structure further comprises a plurality of second semiconductor dies disposed on the first surface of the interconnection structure and overlapped with the plurality of second bonding regions.

15. The package structure according to claim 8, wherein the plurality of passive devices includes a plurality of first passive devices disposed in the plurality of first bump-free zones, and a plurality of second passive devices disposed in the plurality of second bump-free zones, wherein first sidewalls of the plurality of first passive devices are arranged to be in parallel with the first zone boundaries, second sidewalls of the plurality of first passive devices are arranged to be in parallel with the second zone boundaries, and wherein sidewalls of the plurality of second passive devices are arranged to be in parallel with zone boundaries of the plurality of second bump-free zones.

16. A method of fabricating a package structure, comprising:
forming a semiconductor package, which comprises:
forming an interconnection structure;
electrically connecting a plurality of first passive devices to the interconnection structure, wherein the plurality of first passive devices is arranged as a first pattern on the interconnection structure;
electrically connecting a plurality of second passive devices to the interconnection structure, wherein the plurality of second passive devices is arranged as a second pattern on the interconnection structure, and the second pattern is different from the first pattern; and
electrically connecting a plurality of bump structures to the interconnection structure, wherein the plurality of bump structures is laterally surrounding the plurality of first passive devices and the plurality of second passive devices;
bonding the semiconductor package to a circuit substrate, so that the semiconductor package is electrically connected to the circuit substrate, and wherein the plurality of first passive devices and the plurality of second passive devices are located in between the interconnection structure and the circuit substrate, and the plurality of bump structures is electrically connecting the interconnection structure to the circuit substrate.

17. The method according to claim 16, wherein the plurality of first passive devices is arranged as an orthogonal grid pattern on the interconnection structure.

18. The method according to claim 16, wherein the plurality of second passive devices is arranged as a staggered pattern on the interconnection structure.

19. The method according to claim 16, wherein forming the semiconductor package further comprises bonding a plurality of semiconductor dies to a first surface of the interconnection structure, wherein the first surface is opposite to a second surface of the interconnection structure where the plurality of first passive devices and the plurality of second passive devices are located.

20. The method according to claim 16, wherein after bonding the semiconductor package to a circuit substrate, the method further comprises forming an underfill structure covering and contacting the plurality of first passive devices, the plurality of second passive devices and the plurality of bump structures.
